(19) United States
(12) Patent Application Publication
(10) Pub. No.: US 2025/0024706 A1
(43) Pub. Date: Jan. 16, 2025

(54) DISPLAY APPARATUS AND METHOD OF MANUFACTURING THE SAME

(71) Applicant: Samsung Display Co., Ltd., Yongin-si (KR)

(72) Inventors: Hiroshi Okumura, Yongin-si (KR); Jonghoon Choi, Yongin-si (KR)

(21) Appl. No.: 18/739,003

(22) Filed: Jun. 10, 2024

(30) Foreign Application Priority Data
Jul. 11, 2023 (KR) 10-2023-0090031

(51) Int. Cl. H10K 59/121; H10K 59/12

(52) U.S. Cl. CPC H10K 59/1213; H10K 59/1201

(57) ABSTRACT

A display apparatus includes: a display element; a semiconductor pattern including a first area with a first thickness and a second area with a second thickness, wherein the second thickness is greater than the first thickness; a first transistor including a first channel region as a part of the semiconductor pattern and a first gate electrode of which at least a part overlaps the first channel region; and a second transistor including a second channel region as a part of the semiconductor pattern and a second gate electrode of which at least a part overlaps the second channel region, wherein the second area of the semiconductor pattern comprises a corner portion of the semiconductor pattern.

### CROSS-REFERENCE TO RELATED APPLICATION

The present application claims priority to and the benefit of Korean Patent Application No. 10-2023-0090031, filed on Jul. 11, 2023, in the Korean Intellectual Property Office, the entire disclosure of which is incorporated herein by reference.

### BACKGROUND

### 1. Field

Aspects of one or more embodiments relate to a display apparatus and a method of manufacturing the same.

### 2. Description of the Related Art

In general, a display apparatus generally includes a plurality of pixels, and each of the plurality of pixels generally includes a display element and a pixel circuit for controlling the display element. The pixel circuit may include one or more thin-film transistors (TFT), storage capacitors, and wirings.

The number of thin-film transistors electrically connected to one display element may be relatively increased in order to more accurately control whether or not the display element emits light and the degree of light emission.

The above information disclosed in this Background section is only for enhancement of understanding of the background and therefore the information discussed in this Background section does not necessarily constitute prior art.

### SUMMARY

Aspects of one or more embodiments relate to a display apparatus and a method of manufacturing the same, and for example, to a display apparatus in which high-quality images may be displayed and a method of manufacturing the display apparatus.

In some display apparatuses, it may be relatively difficult to display high-quality images.

Aspects of one or more embodiments include a display apparatus in which relatively high-quality images may be displayed and a method of manufacturing the display apparatus. However, these characteristics are merely illustrative, and the scope of embodiments according to the present disclosure is not limited thereto.

Additional aspects will be set forth in part in the description which follows and, in part, will be apparent from the description, or may be learned by practice of the presented embodiments of the disclosure.

According to some embodiments, a display apparatus includes a display element, a semiconductor pattern including a first area with a first thickness and a second area with a second thickness, wherein the second thickness is greater than the first thickness, a first transistor including a first channel region as a part of the semiconductor pattern and a first gate electrode of which at least a part overlaps the first channel region, and a second transistor including a second channel region as a part of the semiconductor pattern and a second gate electrode of which at least a part overlaps the second channel region, wherein the second area of the semiconductor pattern includes a corner portion of the semiconductor pattern.

According to some embodiments, the first transistor may include a driving transistor, and the second transistor may include a switching transistor, and the first channel region may overlap the second area, and the second channel region may overlap the first area.

According to some embodiments, the first channel region and the second channel region may be integrally provided.

According to some embodiments, the semiconductor pattern may include polycrystalline silicon, and the size of a crystalline grain included in the first area may be greater than the size of a crystalline grain included in the second area.

According to some embodiments, in the second channel region, a number of grain boundaries perpendicular to a longitudinal direction of the second channel region may be one or less.

According to some embodiments, in the second channel region, a number of grain boundaries in parallel to the longitudinal direction of the second channel region may be one or less.

According to some embodiments, the display apparatus may further include an insulating layer having a contact hole through which a part of the semiconductor pattern is exposed, and a conductive pattern on the insulating layer and of which at least a part is buried in the contact hole, and the contact hole may overlap the second area.

According to some embodiments, edges of the corner portion of the semiconductor pattern may have an arc shape.

According to some embodiments, a curvature of inner edges of the corner portion of the semiconductor pattern may be greater than a curvature of outer edges of the corner portion of the semiconductor pattern.

According to some embodiments, the first thickness may be about 200 Å to about 300 Å, and the second thickness may be about 400 Å to about 600 Å.

According to some embodiments, a method of manufacturing a display apparatus includes forming an amorphous material layer, forming a sub-pattern including a first preliminary area and a second preliminary area having different thicknesses by half-etching the amorphous material layer, forming a polycrystalline material layer by crystallizing the amorphous material layer having the sub-pattern formed thereon, forming a semiconductor pattern including a first area with a first thickness and a second area with a second thickness greater than the first thickness, by etching the polycrystalline material layer, forming a first transistor including a first channel region and a first gate electrode, forming a second transistor including a second channel region and a second gate electrode, and forming a display element, wherein the second area of the semiconductor pattern includes a corner of the semiconductor pattern.

According to some embodiments, the semiconductor pattern may include polycrystalline silicon, and the size of a grain included in the first area may be greater than the size of a grain included in the second area.

According to some embodiments, the semiconductor pattern may include the first channel region and the second channel region, and the first channel region may overlap the second area, and the second channel region may overlap the first area.

According to some embodiments, in the second channel region, the number of grain boundaries perpendicular to a longitudinal direction of the second channel region may be one or less.

According to some embodiments, the first transistor may control the amount of a current flowing from a second node connected to a power supply voltage line to the display element in response to a voltage applied to a first node.

According to some embodiments, the method may further include forming an insulating layer between the semiconductor pattern and the display element and having a contact hole formed therein, and forming a conductive pattern on the insulating layer and of which at least a part is buried in the contact hole, and the contact hole may overlap the second area.

According to some embodiments, edges of the corner portion of the semiconductor pattern may have an arc shape.

According to some embodiments, a curvature of inner edges of the corner portion of the semiconductor pattern may be greater than a curvature of outer edges of the corner portion of the semiconductor pattern.

According to some embodiments, the first channel region and the second channel region may be integrally provided.

According to some embodiments, the first thickness may be about 200 Å to about 300 Å, and the second thickness may be about 400 Å to about 600 Å.

Other aspects, features, and characteristics other than those described above will be apparent from the detailed description, claims, and drawings for carrying out the disclosure below.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a perspective view schematically illustrating a display apparatus according to some embodiments;

FIG. 2 illustrates a display element provided in any pixel of a display apparatus according to some embodiments and a pixel circuit connected thereto;

FIG. 3 is a layout diagram schematically illustrating positions of thin-film transistors and a capacitor in the pixel of FIG. 2;

FIG. 4 is a layout diagram schematically illustrating a semiconductor pattern of FIG. 3;

FIG. 5 is a schematic cross-sectional view of a display apparatus according to some embodiments, taken along a line I-I′ of FIG. 3;

FIG. 6 is a schematic cross-sectional view of a display apparatus according to some embodiments, taken along a line II-II′ of FIG. 3;

FIG. 7 is a cross-sectional view schematically illustrating a portion of FIG. 4; and

FIGS. 8A through 8G are cross-sectional views schematically illustrating a method of manufacturing a display apparatus, according to some embodiments.

### DETAILED DESCRIPTION

Reference will now be made in more detail to aspects of some embodiments, which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or any suitable combination of a, b, and/or c.

Because various modifications and various embodiments of the present disclosure are possible, specific embodiments are illustrated in the drawings and described in detail in the detailed description. Effects and features of the present disclosure, and a method of achieving them will be apparent with reference to embodiments described below in detail in conjunction with the drawings. However, the present disclosure is not limited to the embodiments disclosed herein, but may be implemented in a variety of forms.

Hereinafter, aspects of some embodiments of the present disclosure will be described in more detail with reference to the accompanying drawings, and the same or corresponding components are denoted by the same reference numerals, and the same reference numerals are assigned and redundant explanations will be omitted.

In the following embodiments, the terms of the first and second, etc. were used for the purpose of distinguishing one element from other element s, not a limited sense.

In the following embodiments, the singular expression includes a plurality of expressions unless the context is clearly different.

In the following embodiments, the terms such as comprising or having are meant to be the features described in the specification, or the element s are present, and the possibility of one or more other features or elements will be added, is not excluded in advance.

In the following embodiments, when a portion such as a layer, a region, an element or the like is on other portions, this is not only when the portion is on other elements, but also when other elements are interposed therebetween.

In the drawings, for convenience of explanation, the sizes of elements may be exaggerated or reduced. For example, because the size and thickness of each component shown in the drawings are arbitrarily indicated for convenience of explanation, the present disclosure is not necessarily limited to the illustration.

In the following embodiments, when a layer, a region, a component, etc. are connected to each other, the layer, the region, and the components are directly connected to each other and/or the layer, the region, and the components may be indirectly connected to each other with other layers, other regions and other components interposed between the layer, the region, and the components. For example, when a layer, a region, a component, etc. are electrically connected to each other in the present specification, the layer, the region, the component, etc. are directly electrically connected to each other, and/or the layer, the region, the component, etc. are indirectly electrically connected to each other with other layers, other regions and other components interposed between the layer, the region, and the components.

In the following embodiments, the x-axis, the y-axis, and the z-axis are not limited to three axes on a Cartesian coordinate system, and may be interpreted in a broad sense including the same. For example, the x-axis, the y-axis, and the z-axis may be perpendicular to each other, but may refer to different directions that are not orthogonal to each other.

In the present specification, “A and/or B” is A, B, or A and B.

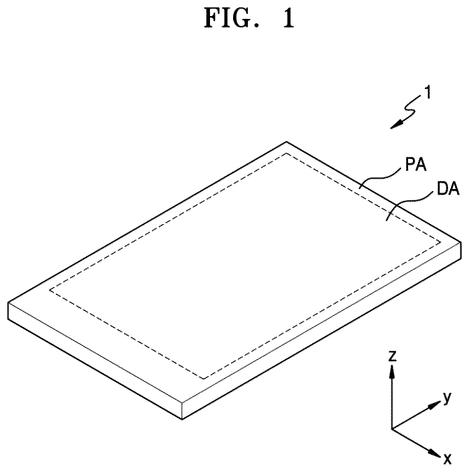

FIG. 1 is a perspective view schematically illustrating a display apparatus 1 according to some embodiments.

The display apparatus 1 according to some embodiments may be implemented as an electronic device such as a smartphone, a mobile phone, a navigation device, a game machine, a television (TV), a head unit for a vehicle, a notebook computer, a laptop computer, a tablet computer, a Personal Media Player (PMP), and a Personal Digital Assistant (PDA), or any other suitable electronic device capable of displaying images. In addition, the electronic device may be a flexible device.

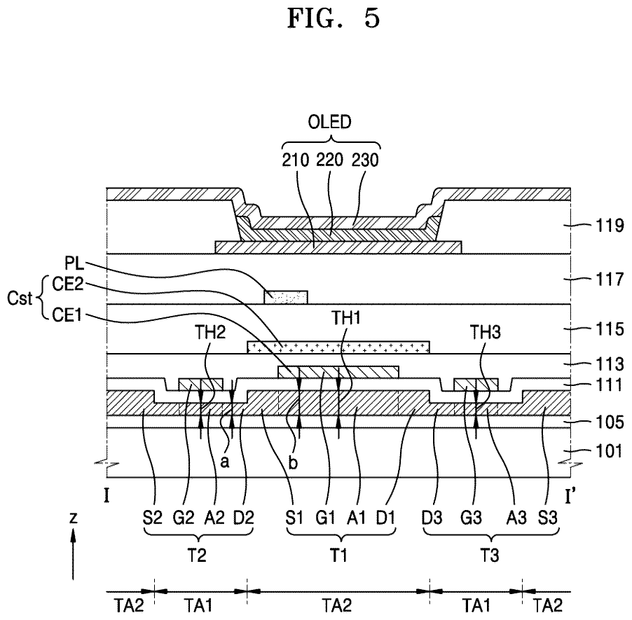

As shown in FIG. 1, the display apparatus 1 according to some embodiments may include a display area DA and a peripheral area PA. The display apparatus 1 may include a substrate (see 101 of FIG. 5), and the shape of the substrate 101 is not limited to a rectangular shape (on an xy plane) as shown in FIG. 1 but may be a variety of shapes, such as a circle and the like. In addition, the substrate 101 may have a bending region and may also be bent in the bending region.

The substrate 101 may include glass or metal. In addition, the substrate 101 may include various flexible or bendable materials, for example, a polymer resin, such as polyethersulfone, polyacrylate, polyether imide, polyethylene naphthalate, polyethylene terephthalate, polyphenylene sulfide, polyarylate, polyimide, polycarbonate, or cellulose acetate propionate.

Of course, the substrate 101 may have a multi-layered structure including two layers including such a polymer resin and a barrier layer including an inorganic material between the layers, and various modifications are possible. In this case, the barrier layer may include silicon oxide, silicon nitride and/or silicon oxynitride, or the like.

A plurality of display elements may be located in the display area DA. According to some embodiments, a display element may be an organic light-emitting diode OLED and may emit red, green, blue, or white light. One (sub)-pixel located in the display area DA of the display apparatus 1 of FIG. 1 may include such an organic light-emitting diode OLED and may also include a thin-film transistor and a capacitor for controlling the degree of light emission of the organic light-emitting diode OLED.

A driving unit, a power supply wiring, and the like may be arranged in the peripheral area PA. In addition, the peripheral area PA may include a pad area, which is an area to which various electronic devices such as a driving integrated circuit and the like, a printed circuit board, etc. are electrically attached.

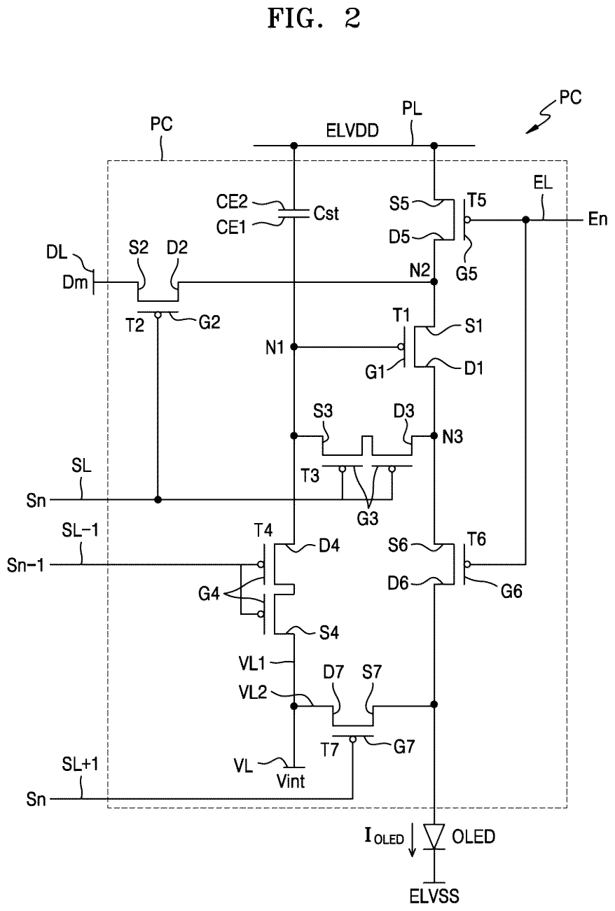

FIG. 2 is an equivalent circuit diagram of a (sub-) pixel of the display apparatus 1 of FIG. 1. In detail, FIG. 2 is an equivalent circuit diagram of a (sub-) pixel located in the display area DA of the display apparatus 1. A pixel circuit unit located in one (sub-) pixel may include a plurality of thin-film transistors T1 to T7 and a storage capacitor Cst. The thin-film transistors T1 to T7 and the storage capacitor Cst may be connected to signal lines SL, SL−1, SL+1, EL, and DL, a first initialization voltage line VL1, a second initialization voltage line VL2, and a power supply voltage line PL.

The signal lines SL, SL−1, SL+1, EL, and DL may include a scan line SL configured to transmit a scan signal Sn to the switching thin-film transistor T2, a previous signal line SL−1 for transmitting a previous scan signal Sn−1 to a first initialization thin-film transistor T4, a subsequent scan line SL+1 for transmitting a scan signal Sn to a second initialization thin-film transistor T7, an emission control line EL for transmitting an emission control signal En to an operation control thin-film transistor T5 and an emission control thin-film transistor T6, and a data line DL crossing the scan line SL and transmitting a data signal Dm to the organic light-emitting diode OLED. The power supply voltage line PL may be configured to transmit a driving voltage ELVDD to a driving thin-film transistor T1, and a first initialization voltage line VL1 may transmit an initialization voltage Vint to the first initialization thin-film transistor T4, and a second initialization voltage line VL2 may transmit an initialization voltage Vint to the second initialization thin-film transistor T7.

A driving gate electrode G1, which is a first gate electrode of the driving thin-film transistor T1 as a first transistor, may be connected to a lower electrode CE1 of the storage capacitor Cst, and a driving source region S1 of the driving thin-film transistor T1 may be connected to the power supply voltage line PL via the operation control thin-film transistor T5, and a driving drain region D1 of the driving thin-film transistor T1 may be electrically connected to a pixel electrode of a main organic light-emitting diode OLED via the emission control thin-film transistor T6. That is, the driving thin-film transistor T1 may control the amount of current flowing through the organic light-emitting diode OLED from a second node N2 connected to the power supply voltage line PL in response to a voltage applied to the first node N1, i.e., a voltage applied to the driving gate electrode G1 of the driving thin-film transistor T1. Thus, the driving thin-film transistor T1 may receive the data signal Dm according to a switching operation of the switching thin-film transistor T2 and may supply a driving current I_{OLED} to the organic light-emitting diode OLED. The operation control thin-film transistor T5 may be between the second node N2 and the power voltage line PL.

The switching gate electrode G2, which is a second gate electrode of the switching thin-film transistor T2 as a second transistor, may be connected to the scan line SL, and the switching source region S2 of the switching thin-film transistor T2 may be connected to the data line DL, and a switching drain region D2 of the switching thin-film transistor T2 may be connected to the second node N2 and may be connected to the driving source region S1 of the driving thin-film transistor T1 and may be connected to the power supply voltage line PL via the operation control thin-film transistor T5. The switching thin-film transistor T2 may be turned on in response to the scan signal Sn transmitted through the scan line SL and may perform a switching operation of transmitting the data signal Dm transmitted to the data line DL to the driving source region S1 of the driving thin-film transistor T1.

The compensation thin-film transistor T3 as a third transistor may be connected between the third node N3 and the first node N1 between the driving thin-film transistor T1 and the organic light-emitting diode OLED, thereby diode-connecting the driving thin-film transistor T1 in response to a voltage applied to the compensation gate electrode G3 as a third gate electrode. That is, the compensation gate electrode G3 of the compensation thin-film transistor T3 may be connected to the scan line SL, and the compensation drain region D3 of the compensation thin-film transistor T3 may be connected to the driving drain region D1 of the driving thin-film transistor T1 and may be connected to a pixel electrode of the organic light-emitting diode OLED via the emission control thin-film transistor T6. In addition, the compensation source region S3 of the compensation thin-film transistor T3 may be connected to the lower electrode CE1 of the storage capacitor Cst, the first initialization drain region D4 of the first initialization thin-film transistor T4, and the driving gate electrode G1 of the driving thin-film transistor T1.

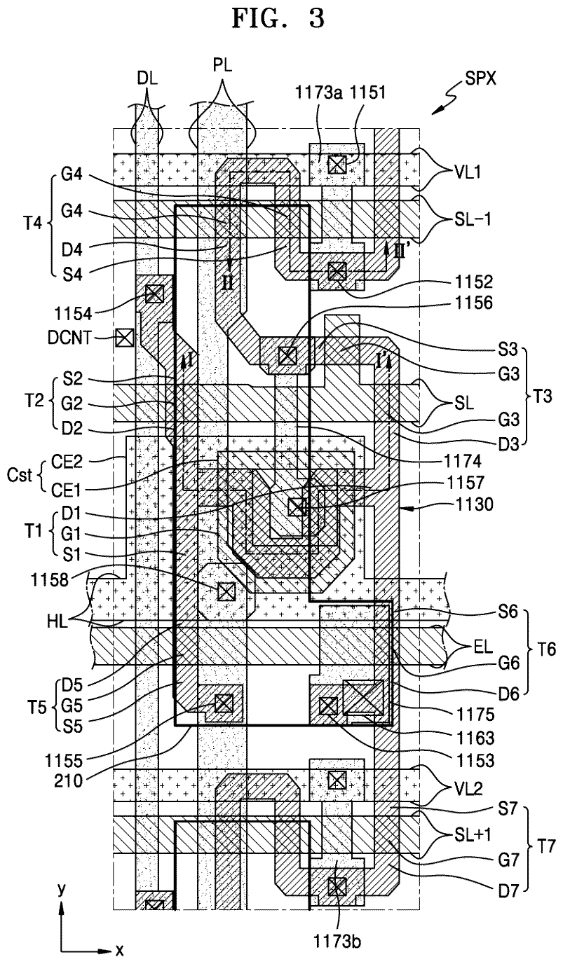

The compensation thin-film transistor T3 may be turned on in response to the scan signal Sn transmitted through the scan line SL and may electrically connect the driving gate electrode G1 to the driving drain region D1 of the driving thin-film transistor T1, thereby diode-connecting the driving thin-film transistor T1. The compensation thin-film transistor T3 may have a dual gate electrode. That is, the compensation gate electrode G3 of the compensation thin-film transistor T3 may have a 3rd-1 gate electrode (see FIG. 3 or the like) and a 3rd-2 gate electrode (see FIG. 3 or the like). Although the compensation thin-film transistor T3 is shown as having two gate electrodes in FIG. 2, embodiments are not limited thereto. The compensation thin-film transistor T3 may have one gate electrode.

The first initialization thin-film transistor T4 as a fourth transistor may be connected between the first node N1 and the first initialization voltage line VL1 and may initialize a voltage of the driving gate electrode G1 in response to the voltage applied to the first initialization gate electrode G4 as a fourth gate electrode. That is, the first initialization gate electrode G4 of the first initialization thin-film transistor T4 may be connected to the previous scan line SL−1, and the first initialization source region S4 of the first initialization thin-film transistor T4 may be connected to the first initialization voltage line VL1. In addition, the first initialization drain region D4 of the first initialization thin-film transistor T4 may be connected to the lower electrode CE1 of the storage capacitor Cst, a compensation source region S3 of the compensation thin-film transistor T3, and a driving gate electrode G1 of the driving thin-film transistor T1. The first initialization thin-film transistor T4 may be turned on in response to the previous scan signal Sn−1 transmitted through the previous scan line SL−1 and may perform an initialization operation of transmitting the initialization voltage Vint to the driving gate electrode G1 of the driving thin-film transistor T1 and initializing the voltage of the driving gate electrode G1 of the driving thin-film transistor T1.

Although the first initialization thin-film transistor T4 is shown as having two gate electrodes in FIG. 2, embodiments are not limited thereto. The first initialization thin-film transistor T4 may have one gate electrode.

The operation control thin-film transistor T5 as a fifth transistor may be connected between the second node N2 and the power supply voltage line PL and may be turned on in response to the voltage applied to the operation control gate electrode G5 as a fifth gate electrode. That is, the operation control gate electrode G5 of the operation control thin-film transistor T5 may be connected to the emission control line EL, and the operation control source region S5 of the operation control thin-film transistor T5 may be connected to the power supply voltage line PL. In addition, the operation control drain region D5 of the operation control thin-film transistor T5 may be connected to the driving source region S1 of the driving thin-film transistor T1 and the switching drain region D2 of the switching thin-film transistor T2.

The emission control thin-film transistor T6 as a sixth transistor may be connected between the third node N3 and the organic light-emitting diode OLED and may be turned on in response to the voltage applied to the emission control gate electrode G6 as a sixth gate electrode from the emission control line EL. That is, the emission control gate electrode G6 of the emission control thin-film transistor T6 may be connected to the emission control line EL, and the emission control source region S6 of the emission control thin film transistor T6 may be connected to the driving drain region D1 of the driving thin-film transistor T1 and the compensation drain region D3 of the compensation thin-film transistor T3. In addition, the emission control drain region D6 of the emission control thin-film transistor T6 may be electrically connected to the second initialization source region S7 of the second initialization thin film transistor T7 and the pixel electrode of the organic light-emitting diode OLED.

The operation control thin-film transistor T5 and the emission control thin-film transistor T6 may be simultaneously turned on in response to an emission control signal En transmitted through the emission control line EL so that the driving voltage ELVDD may be transmitted to the main organic light-emitting diode OLED and the driving current I_{OLED} may flow through the organic light-emitting diode OLED.

A second initialization gate electrode G7, which is a seventh gate electrode of the second initialization thin film transistor T7 as a seventh transistor, may be connected to the subsequent scan line SL+1, and a second initialization source region S7 of the second initialization thin-film transistor T7 may be connected to the emission control drain region D6 of the emission control thin-film transistor T6 and the pixel electrode of the main organic light-emitting diode OLED. In addition, the second initialization drain region D7 of the second initialization thin-film transistor may be connected to the second initialization voltage line VL2.

Because the scan line SL and the subsequent scan line SL+1 are electrically connected to each other, the same scan signal Sn may be applied to the scan line SL and the subsequent scan line SL+1. Thus, the second initialization thin-film transistor T7 may be turned on in response to the scan signal Sn transmitted through the subsequent scan line SL+1 and may perform an operation of initializing the pixel electrode of the organic light-emitting diode OLED. If necessary, the second initialization thin-film transistor T7 may be omitted.

An upper electrode CE2 of the storage capacitor Cst may be connected to the power supply voltage line PL, and a common electrode of the organic light-emitting diode OLED may be connected to a common voltage ELVSS. Thus, the organic light-emitting diode OLED may receive the driving current I_{OLED} from the driving thin-film transistor T1 and may emit light to display an image.

The pixel circuit PC illustrated in FIG. 2 is not limited to the number and arrangement of components shown in FIG. 2. For example, according to some embodiments, the pixel circuit PC may include additional components or fewer components without departing from the spirit and scope of embodiments according to the present disclosure.

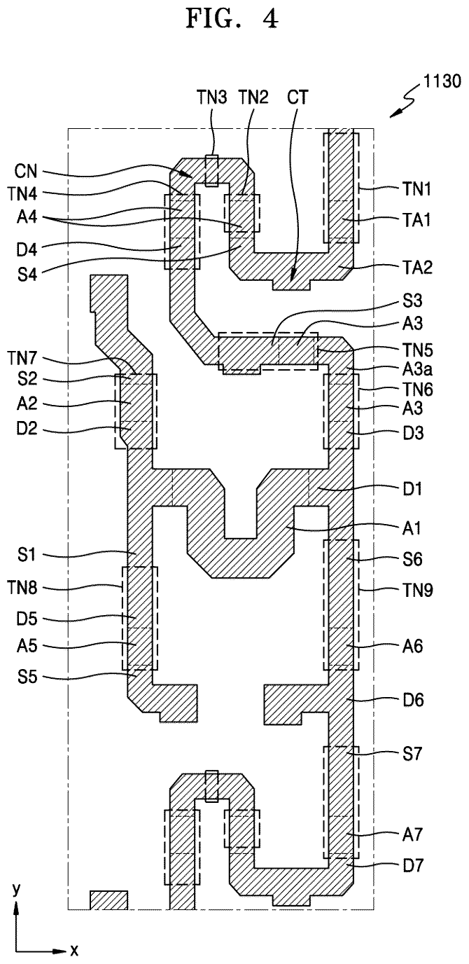

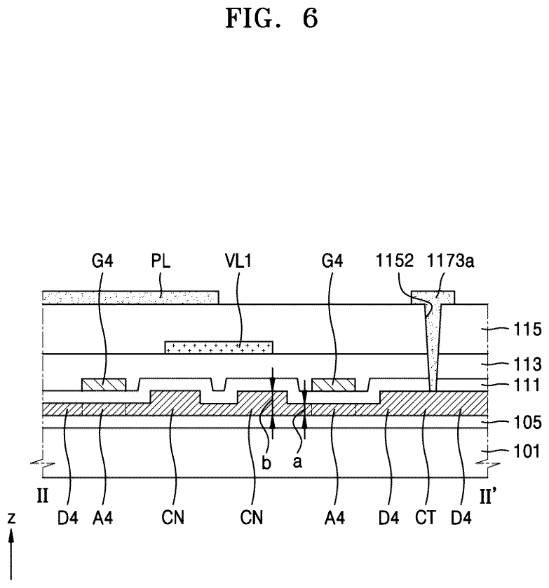

FIG. 3 is a layout diagram schematically showing positions of a plurality of thin-film transistors and capacitors in the (sub-) pixel of FIG. 2, FIG. 4 is a layout diagram schematically showing a semiconductor pattern 1130, which is a part of the display apparatus of FIG. 3, and FIG. 5 is a schematic cross-sectional view of a display apparatus according to some embodiments, taken along a line I-I′ of FIG. 3. FIG. 6 is a schematic cross-sectional view of a display apparatus according to some embodiments, taken along a line II-II′ of FIG. 3. In the cross-sectional view, the size of each component is exaggerated and/or reduced for convenience. This also applies to the cross-sectional views described later.

The driving thin-film transistor T1, the switching thin-film transistor T2, the compensation thin-film transistor T3, the first initialization thin-film transistor T4, the operation control thin-film transistor T5, the emission control thin-film transistor T6, and the second initialization thin-film transistor T7 may be arranged along the semiconductor pattern 1130. Some areas of the semiconductor pattern 1130 may form semiconductor layers of the driving thin-film transistor T1, the switching thin-film transistor T2, the compensation thin-film transistor T3, the first initialization thin-film transistor T4, the operation control thin-film transistor T5, the emission control thin-film transistor T6, and the second initialization thin-film film transistor T7. That is, some areas of the semiconductor pattern 1130 may form a channel region, a source region, or a drain region of a thin-film transistor.

According to some embodiments, the driving thin-film transistor T1 may include a driving semiconductor layer, and the driving semiconductor layer may include a driving channel region A1, a driving source region S1, and a driving drain region D1. For example, the part that overlaps the driving gate electrode (G1 of FIG. 3) of the driving semiconductor layer may be the driving channel region A1.

According to some embodiments, the switching thin-film transistor T2 may include a switching semiconductor layer, and the switching semiconductor layer may include a switching channel region A2, a switching source region S2, and a switching drain region D2. For example, the part that overlaps the switching gate electrode (G2 of FIG. 2) of the switching semiconductor layer may be the switching channel region A2.

According to some embodiments, the compensation thin-film transistor T3 may include a compensation semiconductor layer, and the compensation semiconductor layer may include a compensation channel region A3, a compensation source region S3, and a compensation drain region D3. For example, the part that overlaps the compensation gate electrode (G3 of FIG. 2) of the compensation semiconductor layer may be the compensation channel region A3.

According to some embodiments, the first initialization thin-film transistor T4 may include a first initialization semiconductor, and the first initialization semiconductor layer may include the first initialization channel region A4, the first initialization source region S4, and the first initialization drain region D4. For example, the part that overlaps the first initialization gate electrode (G4 of FIG. 2) of the first initialization semiconductor layer may be the first initialization channel region A4.

According to some embodiments, the operation control thin-film transistor T5 may include an operation control semiconductor layer, and the operation control semiconductor layer may include an operation control channel region A5, an operation control source region S5, and an operation control drain region D5. For example, the part that overlaps the operation control gate electrode (G5 of FIG. 2) of the operation control semiconductor layer may be the operation control channel region A5.

According to some embodiments, the emission control thin-film transistor T6 may include an emission control semiconductor layer, and the emission control semiconductor layer may include an emission control channel region A6, an emission control source region S6, and an emission control drain region D6. For example, the part that overlaps the emission control gate electrode (G6 of FIG. 2) of the emission control semiconductor layer may be the emission control channel region A6.

According to some embodiments, the second initialization thin-film transistor T7 may include a second initialization semiconductor layer, and the second initialization semiconductor layer may include the second initialization channel region A7, the second initialization source region S7, and the second initialization drain region D7. For example, the part that overlaps the second initialization gate electrode (G7 of FIG. 2) of the second initialization semiconductor layer may be the second initialization channel region A7.

As shown in FIG. 4, each of the compensation thin-film transistor T3 and the first initialization thin-film transistor T4 may be provided with two gate electrodes, but embodiments are not limited thereto. Each of the compensation thin-film transistor T3 and the first initialization thin-film transistor T4 may be provided with one gate electrode.

A semiconductor pattern 1130 may be located on the substrate 101. Of course, a buffer layer 105 may be formed on the substrate 101, and the semiconductor pattern 1130 may be formed on the buffer layer 105.

The buffer layer 105 may reduce or block penetration of foreign substances, moisture or external air from the lower portion of the substrate 101 and may provide a flat surface to the substrate 101. The buffer layer 105 may include an inorganic material such as oxide or nitride, an organic material, or an organic/inorganic composite material and may have a single layer or multi-layered structure of the inorganic material and the organic material. According to some embodiments, the buffer layer 105 may have a structure in which a first buffer layer and a second buffer layer are stacked on each other. In this case, the first buffer layer and the second buffer layer may include different materials. For example, the first buffer layer may include silicon nitride and the second buffer layer may include silicon oxide.

In this way, when the first buffer layer includes silicon nitride, the first buffer layer may include hydrogen when forming silicon nitride. Thus, the carrier mobility of the semiconductor pattern 1130 formed on the buffer layer 105 may be enhanced so that electrical characteristics of the thin-film transistor TFT may be relatively enhanced. In addition, the semiconductor pattern 1130 may include a silicon material. In this case, interfacial bonding properties between the semiconductor pattern 1130 including silicon and the second buffer layer including silicon oxide may be enhanced so that the electrical properties of the thin-film transistor TFT may be enhanced.

The semiconductor pattern 1130 may include low temperature poly-silicon (LTPS). Because polysilicon materials have high electron mobility (100 cm²/Vs or more), polysilicon materials have low energy power and excellent reliability. In another example, the semiconductor pattern 1130 may include amorphous silicon (a-Si) and/or oxide semiconductor. Alternatively, some semiconductor layers of a plurality of thin-film transistors may include LTPS and some other semiconductor layers may include a-SI and/or oxide semiconductor.

Source regions and drain regions of the semiconductor pattern 1130 may be doped with impurities, and the impurities may include N-type impurities or P-type impurities. The source region and the drain region may correspond to a source electrode and a drain electrode, respectively. The source region and the drain region may be changed according to characteristics of the transistor. Hereinafter, the terms such as a source region and a drain region instead of a source electrode or a drain electrode are used. In the equivalent circuit diagram of FIG. 2, certain parts of the semiconductor pattern 1130 may be doped with P-type impurities, and thin-film transistors may be implemented as p-channel metal oxide semiconductor field effect transistors (MOSFET) (PMOSs). Of course, other parts of the semiconductor pattern 1130 may be also doped with impurities, which may serve as a wiring to mutually connect the thin-film transistors and/or capacitor.

A first insulating layer 111 may be located on the semiconductor pattern 1130, and the driving gate electrode G1, the scan line SL, the previous scan line SL−1, the subsequent scan line SL+1, and the emission control line EL may be positioned on the first insulating layer 111.

The areas in the scan line SL that overlap the switching and compensation channel regions A2 and A3 of the switching and compensation thin-film transistors T2 and T3 may be the switching gate electrode G2 and the compensation gate electrode G3, respectively, and the area in the previous scan line SL−1 that overlaps the first initialization channel region A4 of the first initialization thin-film transistor T4 may be the first initialization gate electrode G4. In addition, the area in the subsequent scan line SL+1 that overlaps the second initialization channel region A7 of the second initialization thin-film transistor T7 may be the second initialization gate electrode G7, and the areas in the emission control line EL that overlap the operation control and emission control channel regions A5 and A6 of the operation control and emission control thin-film transistors T5 and T6 may be the operation control gate electrode G5 and the emission control gate electrode G6, respectively.

The driving gate electrode G1, the scan line SL, the previous scan line SL−1, the subsequent scan line SL+1, and the emission control line EL may include conductive materials including molybdenum (Mo), aluminum (Al), copper (Cu), and titanium (Ti), and the like and may have a multi-layered structure or a single layer structure including the above-described materials. According to some embodiments, the driving gate electrode G1, the scan line SL, the previous scan line SL−1, the subsequent scan line SL+1, and the emission control line EL may have a multi-layered structure of Mo/Al or a multi-layered structure of Mo/Al/Mo.

A second insulating layer 113 may be provided on the driving gate electrode G1, the scan line SL, the previous scan line SL−1, the subsequent scan line SL+1, and the emission control line EL. The second insulating layer 113 may include silicon (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

An electrode voltage line HL, a first initialization voltage line VL1, and a second initialization voltage line VL2 may be arranged on the second insulating layer 113. The electrode voltage line HL may cover at least a portion of the driving gate electrode G1 and may form a storage capacitor Cst together with the drive gate electrode G1.

The lower electrode CE1 of the storage capacitor Cst may be formed integrally with the driving gate electrode G1 of the driving thin-film transistor T1. For example, the driving gate electrode G1 of the driving thin-film transistor T1 may function as the lower electrode CE1 of the storage capacitor Cst. The area in the electrode voltage line HL that overlaps the driving gate electrode G1 may be an upper electrode CE2 of the storage capacitor Cst. Thus, the second insulating layer 113 may function as a dielectric layer of the storage capacitor Cst.

The electrode voltage line HL, the first initialization voltage line VL1 and the second initialization voltage line VL2 may include conductive materials including Mo, Al, Cu, Ti, and the like and may have a multi-layered structure or a single layer structure including the above-described materials. In an example, the electrode voltage line HL, the first initialization voltage line VL1, and the second initialization voltage line VL2 may have a multi-layered structure of Mo/Al or a multi-layered structure of Mo/Al/Mo.

The interlayer insulating layer 115 may be located on the electrode voltage line HL, the first initialization voltage line VL1, and the second initialization voltage line VL2. The interlayer insulating layer 115 may include silicon (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

A data line DL, a power supply voltage line PL, first and second initialization connection lines 1173a and 1173b, a node connection line 1174, and a contact metal 1175 may be arranged on the interlayer insulating layer 115. The data line DL, the power supply voltage line PL, the node connection line 1174, and the contact metal 1175 may include conductive materials including Mo, Al, Cu, Ti, and the like and may have a multi-layered structure or a single layer structure including the above-described materials. In an example, the data line DL, the power supply voltage line PL, the node connection line 1174, and the contact metal 1175 may have a multi-layered structure of Ti/Al/Ti.

The data line DL may be connected to a switching source region S2 of the switching thin-film transistor T2 through the contact hole 1154. If necessary, a part of the data line DL may be understood as a switching source electrode.

The power supply voltage line PL may be connected to the upper electrode CE2 of the storage capacitor Cst through a contact hole 1158 formed in the interlayer insulating layer 115. Thus, the electrode voltage line HL may have the same voltage level (constant voltage) as the power supply voltage line PL. In addition, the power supply voltage line PL may be connected to the operation control drain region D5 through the contact hole 1155.

The first initialization voltage line VL1 may be connected to the first initialization thin-film transistor T4 through the first initialization connection line 1173a, and the second initialization voltage line VL2 may be connected to the second initialization thin-film transistor T7 through the second initialization connection line 1173b. On the other hand, the first initialization voltage line VL1 and the second initialization voltage line VL2 may have the same constant voltage (e.g., −2 V etc.).

One end of the node connection line 1174 may be connected to the compensation source region S3 through the contact hole 1156, and the other end of the node connection line 1174 may be connected to the driving gate electrode G1 through the contact hole 1157.

The contact metal 1175 may be connected to the semiconductor layer of the emission control thin-film transistor T6 through the contact hole 1153 through which the interlayer insulating layer 115, the second insulating layer 113 and the first insulating layer 111 pass. The contact metal 1175 may be connected to the pixel electrode 210 of the organic light-emitting diode OLED through the contact hole 1163. Thus, the emission control thin-film transistor T6 may be electrically connected to the pixel electrode 210 of the organic light-emitting diode OLED.

A planarization layer 117 may be located on the data line DL, the power supply voltage line PL, the first and second initialization connection lines 1173a and 1173b, the node connection line 1174, and the contact metal 1175, and the organic light-emitting diode OLED may be located on the planarization layer 117.

On the other hand, FIG. 2 illustrates one pixel circuit PC, and FIG. 3 shows the structure of one (sub-) pixel circuit SPX, but a plurality of sub-pixels SPX having the same pixel circuit PC may be arranged in a first direction (an x-axis direction) and a second direction (a y-axis direction). In this case, the first initialization voltage line VL1, the previous scan line SL−1, the second initialization voltage line VL2, and the subsequent scan Line SL+1 may be shared in two pixel circuits PCs located adjacent to each other in the second direction (a y-axis direction).

That is, the first initialization voltage line VL1 and the previous scan line SL−1 may be electrically connected to the second initialization thin-film transistor of another pixel circuit PC located on the upper portion (a +y direction) of the pixel circuit PC shown in FIG. 3, in the second direction (a y-axis direction) based on the drawings. Thus, the previous scan signal applied to the previous scan line SL−1 may be transmitted as a subsequent scan signal to the second initialization thin-film transistor of another pixel circuit PC. Similarly, the second initialization voltage line VL2 and the subsequent scan line SL+1 may be electrically connected to the first initialization thin-film transistor of another pixel circuit PC located adjacent to the lower portion (a −y direction) of the pixel circuit PC shown in FIG. 3 in the second direction (a y-axis direction) based on the drawings, and may be configured to transmit a previous scan signal and an initialization voltage.

Referring back to FIGS. 3 through 5, the planarization layer 117 may have a flat upper surface on which the pixel electrode 210 may be flatly formed. The planarization layer 117 may include an organic material and may have a single layer or multi-layered structure. The planarization layer 117 may include a general common use polymer such as benzocyclobutene (BCB), polyimide, hexamethyldisiloxane (HMDSO), polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, or a vinyl alcohol-based polymer, or the like. The planarization layer 117 may also include an inorganic material. The planarization layer 117 may include silicon (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO₂). When the planarization layer 117 includes an inorganic material, chemical planarization polishing may be performed as occasions demand. The planarization layer 117 may include both an organic material and an inorganic material.

The organic light-emitting diode OLED may include the pixel electrode 210, a common electrode 230, and an intermediate layer 220 located between the pixel electrode 210 and the common electrode 230 and including a light-emitting layer.

The pixel electrode 210 may be connected to the contact metal 1175 through the contact hole 1163, and the contact metal 1175 may be connected to the emission control drain region through the contact hole 1153. The pixel electrode 210 may be a (semi-) transparent electrode or a reflective electrode. In some embodiments, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), and a compound thereof, and a transparent or a semi-transparent electrode layer formed on the reflective layer. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). In some embodiments, the pixel electrode 210 may have a stack structure of ITO/Ag/ITO.

A pixel-defining layer 119 may be located on the planarization layer 117, and the pixel-defining layer 119 may have an opening through which the center of the pixel electrode 210 is exposed, thereby defining an emission region of a pixel. In addition, the pixel-defining layer 119 may be configured to increase a distance between edges of the pixel electrode 210 and the common electrode 230 on the pixel electrode 210 to prevent arcs, etc. from occurring on the edges of the pixel electrode 210. The pixel-defining layer 119 may be formed of an organic insulating material such as polyimide, polyamide, acryl resin, BCB, HMDSO, a phenol resin, or the like through a method such as spin coating or the like.

The pixel-defining layer 119 may include an organic insulating material. Alternatively, the pixel-defining layer 119 may include an inorganic insulating material such as silicon nitride, silicon oxynitride, or silicon oxide. Alternatively, the pixel-defining layer 119 may include an organic insulating material and an inorganic insulating material. According to some embodiments, the pixel-defining layer 119 may include a light blocking material and may provide black. The light blocking material may include carbon black, carbon nanotubes, a resin or paste including a black dye, metal particles, such as Ni, Al, Mo and alloys thereof, metal oxide particles (e.g., chromium oxide), or metal nitride particles (e.g., chromium nitride). When the pixel-defining layer 119 includes a light blocking material, external light reflection caused by metal structures located under the pixel-defining layer 119 may be reduced.

The intermediate layer 220 may include an organic light-emitting layer. The organic light-emitting layer may include an organic material including a fluorescent or phosphorous material that emits red, green, blue, or white light. The organic light-emitting layer may be formed of a low molecular weight organic material or polymer organic material, and a functional layer, such as a hole transport layer (HTL), a hole injection layer (HIL), an electron transport layer (ETL), and an electron injection layer (EIL), may be further selectively arranged under and on the organic light-emitting layer. The intermediate layer 220 may be arranged to correspond to each of the plurality of pixel electrodes 210. However, embodiments are not limited thereto, and a layer, such as an HTL, an HIL, an ETL or an EIL, among layers included in the intermediate layer 220 may be integrally formed over the plurality of pixel electrodes 210.

The common electrode 230 may be a transparent electrode or a reflective electrode. In some embodiments, the common electrode 230 may be a transparent or semi-transparent electrode and may include a metal thin layer having a small work function and including lithium (Li), calcium (Ca), lithium fluoride (LiF)/Al, Al, aluminum (Ag), Mg, and a compound thereof. In addition, the common electrode 230 may further include a transparent conductive oxide (TCO) layer, such as ITO, IZO, ZnO, or In₂O₃, in addition to the metal thin layer. The common electrode 230 may be integrally formed to correspond to the plurality of pixel electrodes 210.

An encapsulation layer including a first inorganic encapsulation layer, a second inorganic encapsulation layer, and an organic encapsulation layer between the first inorganic encapsulation layer 310 and the second inorganic encapsulation layer 320 may be located on the common electrode 230.

The first inorganic encapsulation layer 310 and the second inorganic encapsulation layer 320 may include silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The organic encapsulation layer 330 may include polyethylene terephthalate, polyethylene naphthalate, polycarbonate, polyimide, polyethylene sulfonate, polyoxymethylene, polyarylate, hexamethyldisiloxane (HMDSO), acryl-based resin (e.g., polymethylmethacrylate, polyacrylic acid, etc.), or any combination thereof.

According to some embodiments, the semiconductor pattern 1130 may include a first area TA1 having a first thickness a and a second area TA2 having a second thickness b, wherein the second thickness b is greater than the first thickness a. The semiconductor pattern 1130 may have a shape in which the first area TA1 having the first thickness a and the second area TA2 having the second thickness b are alternately connected to each other. The first thickness may be about 200 Å to about 300 Å. The first thickness a may be approximately 250 Å. The second thickness b may be about 400 Å to about 600 Å. The second thickness b may be approximately 500 Å.

According to some embodiments, the semiconductor pattern 1130 may include crystalloid silicon. Hereinafter, the grain size may be the size of a crystalline grain. The grain size of the first area TA1 of the semiconductor pattern 1130 may be greater than the grain size of the second area TA2 of the semiconductor pattern 1130. Thus, the first area TA1 may include a grain boundary in a smaller number than the number of second areas TA2. According to some embodiments, the grain boundary perpendicular to the longitudinal direction of the semiconductor pattern 1130 in the first area TA1 may be provided as one or less. Thus, the mobility of electrons may be enhanced. According to some embodiments, the grain boundary in parallel to the longitudinal direction of the semiconductor pattern 1130 in the first area TA1 may be provided as one or less. Thus, the semiconductor pattern 1130 may be uniformly formed.

According to some embodiments, the first area TA1 may include channel regions A2 to A7 of a plurality of thin-film transistors T2 to T7 except for the driving thin-film transistor T1, and the second area TA2 may include the driving channel region A1 of the driving thin-film transistor T1.

Referring to FIGS. 3 through 5, the first area TA1 may include first through ninth sub-regions TN1 to TN9. The first area TA1 may include a first sub-region TN1 that overlaps the second initialization channel region A7, second and fourth sub-regions TN2 and TN4 that overlap the first initialization channel region A4, a third sub-region TN3, fifth and sixth sub-regions TN5 and TN6 that overlap the compensation channel region A3, an eighth sub-region TN8 that overlaps the operation control channel region A5, and a ninth sub-region TN9 that overlaps the emission control channel region A6. The first through ninth sub-regions TN1 to TN9 may be spaced apart from each other. The second area TA2 may be a region between the spaced first through ninth sub-regions TN1 to TN9.

That is, the switching channel region A2, the compensation channel region A3, the first initialization channel region A4, the operation control channel region A5, the emission control channel region A6, and the second initialization channel region A7 may have the first thickness a, and the driving channel region A1 may have the second thickness b, wherein the second thickness b is greater than the first thickness a.

For example, referring to FIG. 6, the driving thin-film transistor T1 may include a driving channel region A1 and a driving gate electrode G1, the switching thin-film transistor T2 may include a switching channel region A2 and a switching gate electrode G2, and the compensation thin-film transistor T3 may include a compensation channel region A3 and a compensation gate electrode G3. A thickness TH1 of the driving channel region A1 may be provided to be greater than a thickness TH2 of the switching channel region A2 and a thickness TH3 of the compensation channel region A3. The driving channel region A1 may be provided as having the second thickness b, and the thickness TH3 of the switching channel region A2 and the compensation channel region A3 may be provided as having the first thickness a.

In the present specification, the first thickness and the second thickness may not only mean specific values but also arbitrary thicknesses within a certain range. For example, the driving channel region A1 having the second thickness b and the switching channel region A2 and the compensation channel region A3 having the first thickness a mean that not only the switching channel region A2 and the compensation channel region A3 have the same thickness, but also each of the switching channel region A2 and the compensation channel region A3 has a different thickness within a smaller range than the thickness of the driving channel region A1. In other words, one region of the semiconductor pattern 1130 having the first thickness a may mean as having an arbitrary value within a smaller range than the second thickness b.

A subthreshold current refers to a current flowing even when a voltage that is a threshold voltage or less is applied to a gate. The subthreshold current may operate even in a state where a thin-film transistor is turned off, thereby causing unintended power consumption. The switching channel region A2, the compensation channel region A3, the first initialization channel region A4, the operation control channel region A5, the emission control channel region A6, and the second initialization channel region A7 may have comparatively small thicknesses so that the subthreshold current may be reduced, the uniformity of the thin-film transistor may be enhanced and luminance uniformity may be enhanced.

In addition, when the switching channel region A2, the compensation channel region A3, the first initialization channel region A4, the operation control channel region A5, the emission control channel region A6, and the second initialization channel region A7 include crystalloid silicon, they may have a comparatively large grain size so that the mobility of electrons may be enhanced and the area of the thin-film transistor may be reduced. Thus, the resolution of the display apparatus may be enhanced. The driving channel region A1 may have a comparatively large thickness so that a driving range may be increased and sufficient gray scales may be represented.

Referring to FIGS. 4 and 6, according to some embodiments, the semiconductor pattern 1130 may include a corner portion CN and a contact portion CT. The corner portion CN of the semiconductor pattern 1130 may be a region in which a portion of the semiconductor pattern 1130 extending in the first direction (e.g., an x direction) and a portion of the semiconductor pattern 1130 extending in the second direction (e.g., a y direction) meet each other. The corner portion CN may be located between the spaced first areas TA1. For example, the corner portion CN may be a region between the second sub-region TN2 and the third sub-region TN3 but may include a region between the third sub-region TN3 and the fourth sub-region TN4. The corner portion CN may correspond to the second area TA2 having the second thickness b. The corner portion CN in the semiconductor pattern 1130 may be provided to be thicker than the plurality of channel regions A2 to A7 except for the driving channel region A1.

According to some embodiments, the display apparatus may be a flexible display apparatus including a flexible display panel. The corner portion CN of the semiconductor pattern 1130 has a relatively thick second thickness b so that resistance to the stress applied according to the deformation of a panel may be reinforced. Accordingly, the occurrence of cracks in the display apparatus may be prevented and reliability may be secured.

According to some embodiments, the contact portion CT may be one region of the semiconductor pattern 1130 electrically connected to a conductive pattern located on the semiconductor pattern 1130. An insulating layer may be between the semiconductor pattern 1130 and the conductive pattern, and the insulating layer may have a contact hole through which the contact portion CT of the semiconductor pattern 1130 is exposed. The contact portion CT may overlap the contact hole. The conductive pattern may be buried in the contact hole of the insulating layer and may be electrically connected to the semiconductor pattern 1130.

Referring to FIG. 3, the conductive pattern may be at least one of the data line DL, the first and second initialization connection lines 1173a and 1173b, the power supply voltage line PL, the node connection line 1174, or the contact metal 1175. The contact hole may be provided through at least a portion of the first insulating layer 111, the second insulating layer 113, the interlayer insulating layer 115, and the planarization layer 117 between the semiconductor pattern 1130 and the conductive pattern.

The data line DL may be connected to the switching source region S2 that is a portion of the semiconductor pattern 1130 through the contact hole 1154. The first initialization connection line 1173a may be connected to the first initialization source region S4 that is a portion of the semiconductor pattern 1130 through the contact hole 1152. The power supply voltage line PL may be connected to the operation control drain region D5 that is a portion of the semiconductor pattern 1130 through the contact hole 1155. The node connection line 1174 may be connected to the compensation source region S3 that is a portion of the semiconductor pattern 1130 through the contact hole 1156. The contact metal 1175 may be connected to the emission control drain region D6 through the contact hole 1153. In this case, the contact portion CT of the semiconductor pattern 1130 may be a region that overlaps the plurality of contact holes 1152, 1153, 1154, 1155, and 1156.

According to some embodiments, the contact portion CT may be included in the second area TA2 of the semiconductor pattern 1130. The contact portion CT may have a comparatively thick second thickness b so that contact defects caused by over-etching may be prevented and yield may be enhanced.

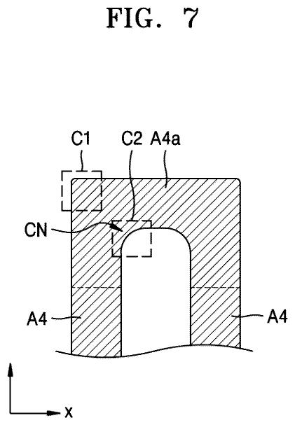

FIG. 7 is a cross-sectional view schematically showing a portion of FIG. 4, which illustrates a portion of the corner portion CN of the semiconductor pattern 1130. Stress may be concentrated on the corner portion CN of the semiconductor pattern 1130. Edges of the corner portion CN of the semiconductor pattern 1130 may be provided in an arc shape so that resistance caused by stress may be enhanced.

Among an outer side C1 and an inner side C2 of the corner portion CN, in particular, the inner side C2 may be a point where stress is concentrated. According to some embodiments, edges of the inner side C2 and edges of the outer side C1 of the corner portion CN may be provided in an arc shape, and the curvature of the edges of the inner side C2 may be formed to be greater than the curvature of the edges of the outer side C1 so that cracks of the display apparatus may be prevented.

According to some embodiments, the semiconductor pattern 1130 includes the first area TA1 having the first thickness a and the second area TA2 having the second thickness b. The second thickness b may be provided to be greater than the first thickness a. The second area TA2 having a comparatively large thickness may overlap the driving channel region A1 of the driving thin-film transistor T1, the corner portion CN, and the contact portion CT. The first area TA1 having a comparatively small thickness may overlap the plurality of channel regions A2 to A7 except for the driving channel region A1. As described above, the area may be divided from the semiconductor pattern 1130 to control the thickness so that the characteristics of the display apparatus may be adjusted without increasing the area of the circuit.

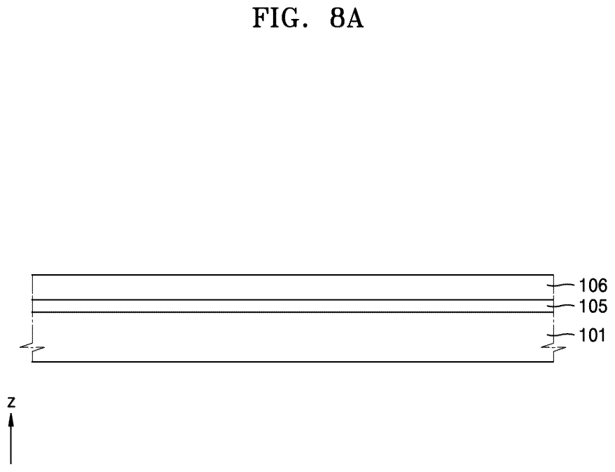

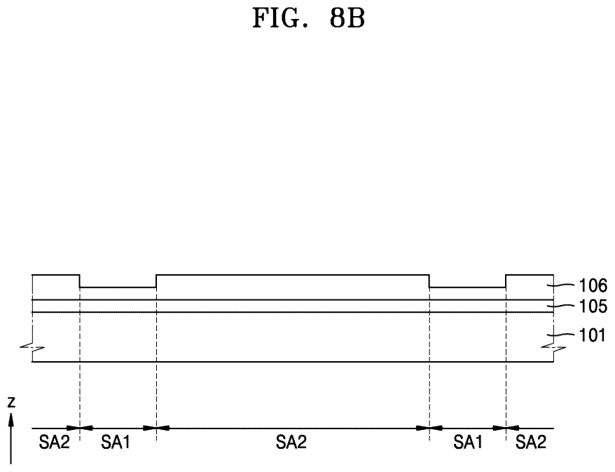

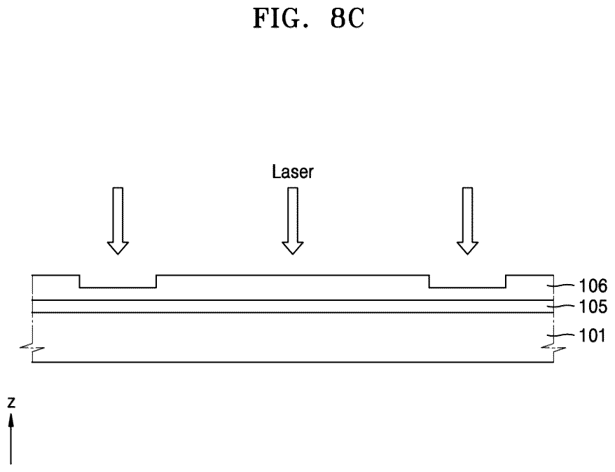

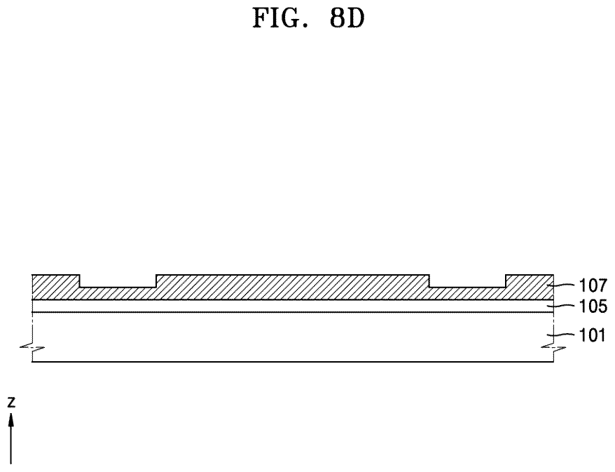

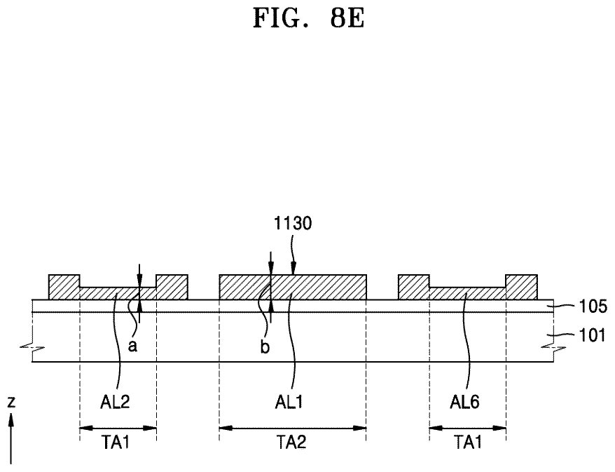

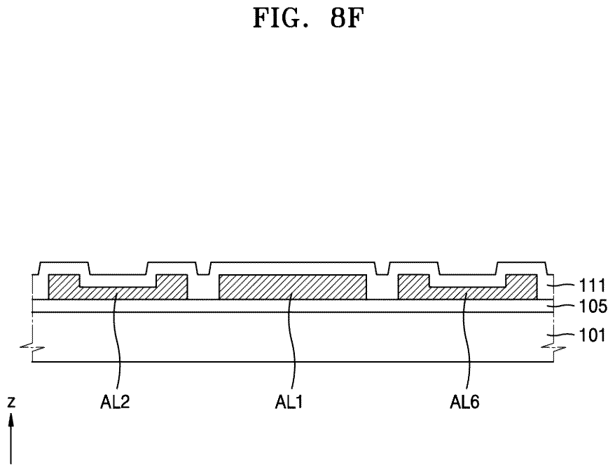

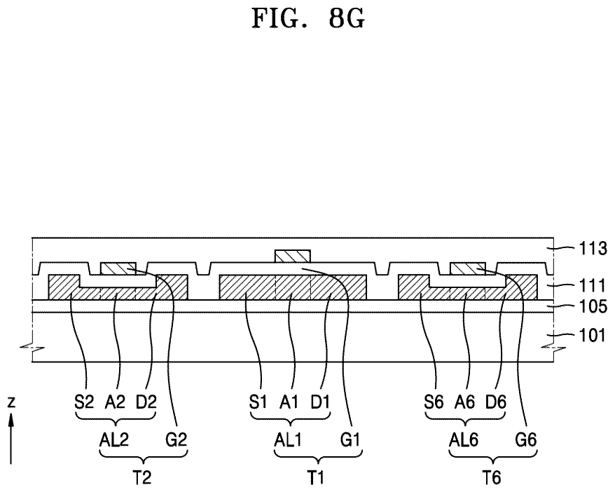

FIGS. 8A through 8G are cross-sectional views schematically illustrating a method of manufacturing a display apparatus, according to some embodiments. For example, the display apparatus according to some embodiments may include a plurality of pixel circuits (PC of FIG. 2), and each of the plurality of pixel circuits PC may include a plurality of thin-film transistors T1 to T7, and FIGS. 8A through 8g are cross-sectional views illustrating a method of manufacturing the driving thin-film transistor T1, the switching thin-film transistor T2, and the emission control thin-film transistor T8 among the plurality of thin-film transistors T1 to T7. According to some embodiments, the compensation thin-film transistor T3, the first initialization thin-film transistor T4, the operation control thin-film transistor T5, and the second initialization thin-film transistor T7 may be manufactured by using the same method as a method of manufacturing the switching thin-film transistor T2.

Referring to FIGS. 8A through 8G, the method of manufacturing the display apparatus according to some embodiments may include forming an amorphous material layer 106 on a substrate 101, forming a sub-pattern including a first preliminary area SA1 and a second preliminary area SA2 having different thicknesses by half-etching the amorphous material layer 106, forming a polycrystalline material layer 107 by crystallizing the sub-pattern, and forming a semiconductor pattern 1130 including a first area TA1 with a first thickness a and a second area TA2 with a second thickness b by etching the polycrystalline material layer 107.

Referring to FIGS. 8A and 8B, a buffer layer 105 may be formed on the substrate 101, and an amorphous material layer 106 may be formed on the buffer layer 105. The amorphous material layer 106 may be an amorphous silicon layer. Subsequently, the sub-pattern may be formed by half-etching the amorphous material layer 106. The sub-pattern may be an amorphous material layer 106 which is divided into the first preliminary area SA1 and the second preliminary area SA2, and the first preliminary area SA1 may have a smaller thickness than the second preliminary area SA2. For example, the thickness of the first preliminary area SA1 may be about 200 Å to about 300 Å, and the thickness of the second preliminary area SA2 may be about 400 Å to about 600 Å.

Referring to FIGS. 8C and 8D, the amorphous material layer 106 having the sub-pattern formed thereon may be crystallized so that a polycrystalline material layer 107 may be formed. According to some embodiments, the polycrystalline material layer 107 may be formed by using excimer laser annealing (ELA). That is, the amorphous material layer 106 may be crystallized by laser irradiation so that the polycrystalline material layer 107 may be formed. According to some embodiments, crystallization caused by complete melting of an amorphous material may occur in the first preliminary area SA1, and crystallization caused by near complete melting of the amorphous material may occur in the second preliminary area SA2. To this end, in half-etching of FIG. 8B, the thickness of the first preliminary area SA1 and the thickness of the second preliminary area SA2 may be adjusted in advance.

As in the first preliminary area SA1, the amorphous material is complete melted, the grain size crystallized in the first preliminary area SA1 may be provided to be greater than the size of grain crystallized in the second preliminary area SA2. The number of grain boundaries formed in the first preliminary area SA1 may be less than the number of grain boundaries formed in the second preliminary area SA2.

Referring to FIGS. 8E through 8G, the polycrystalline material layer may be etched so that the semiconductor pattern 1130 may be formed. The area in the semiconductor pattern 1130 corresponding to the first preliminary area SA1 may be formed as the first area TA1 having the first thickness a, and the area in the semiconductor pattern 1130 corresponding to the second preliminary area SA2 may be formed as a second area TA2 having a second thickness b, wherein the second thickness b is greater than the first thickness a. FIGS. 8A through 8E illustrate a semiconductor layer of a thin-film transistor of the semiconductor pattern 1130, and this may be also applied to the corner portion CN and the contact portion CT described above with reference to FIGS. 2 through 7.

The semiconductor pattern 1130 may include a driving semiconductor layer AL1 of the driving thin-film transistor T1, a switching semiconductor layer AL2 of the switching transistor T2, and an emission control semiconductor layer AL6 of the emission control thin-film transistor T6. The first area TA1 may include a switching semiconductor layer AL2 and an emission control semiconductor layer AL6, and the second area TA2 may include a driving semiconductor layer AL1. That is, the driving semiconductor layer AL1 may have a comparatively thick second thickness b, and at least a portion of the switching semiconductor layer AL2 and at least a portion of the emission control semiconductor layer AL6 may have a comparatively thin first thickness a. The switching channel region A2 and the emission control channel region A6 may have the first thickness a.

Subsequently, a first insulating layer 111 may be formed to cover the semiconductor pattern 1130, and a driving gate electrode G1, a switching gate electrode G2, and an emission control gate electrode G6 may be formed on the first insulating layer 111.

The driving source region S1 and the driving drain region D1 of the driving thin-film transistor T1 may be formed through impurity doping. In this case, the area in the driving semiconductor layer AL1 that overlaps the driving gate electrode G1 may be formed as the driving channel region A1. Thus, impurities may be doped in part of the driving semiconductor layer AL1 through impurity doping so that the driving semiconductor layer AL1 may be divided into the driving source region S1, the driving channel region A1, and the driving drain region D1. Similarly, the switching source region S2 and the switching drain region D2 of the switching thin-film transistor T2 may be formed through impurity doping, and the emission control source region S6 and the emission control drain region D6 of the emission control thin-film transistor T6 may be formed. According to some embodiments, the semiconductor layers of the rest of the thin-film transistors may be also doped to be divided into a source region, a channel region, and a drain region. A second insulating layer 113 may be formed to cover the gate electrode.

According to some embodiments, as described above, a display apparatus in which relatively high-quality images may be displayed and a method of manufacturing the display apparatus may be provided. Of course, the scope of embodiments according to the present disclosure is not limited by these characteristics.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising:
a display element;
a semiconductor pattern including a first area with a first thickness and a second area with a second thickness, wherein the second thickness is greater than the first thickness;
a first transistor including a first channel region as a part of the semiconductor pattern and a first gate electrode of which at least a part overlaps the first channel region; and
a second transistor including a second channel region as a part of the semiconductor pattern and a second gate electrode of which at least a part overlaps the second channel region,
wherein the second area of the semiconductor pattern comprises a corner portion of the semiconductor pattern.

2. The display apparatus of claim 1, wherein the first transistor includes a driving transistor, and the second transistor includes a switching transistor, and
the first channel region overlaps the second area, and the second channel region overlaps the first area.

3. The display apparatus of claim 2, wherein the first channel region and the second channel region are integrally provided.

4. The display apparatus of claim 2, wherein the semiconductor pattern comprises polycrystalline silicon, and
a size of a crystalline grain included in the first area is greater than a size of a crystalline grain included in the second area.

5. The display apparatus of claim 4, wherein, in the second channel region, a number of grain boundaries perpendicular to a longitudinal direction of the second channel region is one or less.

6. The display apparatus of claim 5, wherein, in the second channel region, a number of grain boundaries in parallel to the longitudinal direction of the second channel region is one or less.

7. The display apparatus of claim 1, further comprising:
an insulating layer having a contact hole through which a part of the semiconductor pattern is exposed; and
a conductive pattern on the insulating layer and of which at least a part is buried in the contact hole,
wherein the contact hole overlaps the second area.

8. The display apparatus of claim 1, wherein edges of the corner portion of the semiconductor pattern have an arc shape.

9. The display apparatus of claim 8, wherein a curvature of inner edges of the corner portion of the semiconductor pattern is greater than a curvature of outer edges of the corner portion of the semiconductor pattern.

10. The display apparatus of claim 1, wherein the first thickness is 200 Å to 300 Å, and the second thickness is 400 Å to 600 Å.

11. A method of manufacturing a display apparatus, the method comprising:
forming an amorphous material layer;
forming a sub-pattern including a first preliminary area and a second preliminary area having different thicknesses by half-etching the amorphous material layer;
forming a polycrystalline material layer by crystallizing the amorphous material layer having the sub-pattern formed thereon;
forming a semiconductor pattern including a first area with a first thickness and a second area with a second thickness greater than the first thickness, by etching the polycrystalline material layer;
forming a first transistor including a first channel region and a first gate electrode;
forming a second transistor including a second channel region and a second gate electrode; and
forming a display element,
wherein the second area of the semiconductor pattern comprises a corner portion of the semiconductor pattern.

12. The method of claim 11, wherein the semiconductor pattern comprises polycrystalline silicon, and
a size of a crystalline grain included in the first area is greater than a size of a crystalline grain included in the second area.

13. The method of claim 11, wherein the semiconductor pattern comprises the first channel region and the second channel region, and
the first channel region overlaps the second area, and the second channel region overlaps the first area.

14. The method of claim 13, wherein, in the second channel region, a number of grain boundaries perpendicular to a longitudinal direction of the second channel region is one or less.

15. The method of claim 13, wherein the first transistor is configured to control an amount of current flowing from a second node connected to a power supply voltage line to the display element in response to a voltage applied to a first node.

16. The method of claim 11, further comprising:
forming an insulating layer between the semiconductor pattern and the display element and having a contact hole formed therein; and
forming a conductive pattern on the insulating layer and of which at least a part is buried in the contact hole,
wherein the contact hole overlaps the second area.

17. The method of claim 11, wherein edges of the corner portion of the semiconductor pattern have an arc shape.

18. The method of claim 16, wherein a curvature of inner edges of the corner portion of the semiconductor pattern is greater than a curvature of outer edges of the corner portion of the semiconductor pattern.

19. The method of claim 11, the first channel region and the second channel region are integrally provided.

20. The method of claim 11, wherein the first thickness is 200 Å to 300 Å, and the second thickness is 400 Å to 600 Å.
